(19) United States
(12) Patent Application Publication
(10) Pub. No.: US 2009/0025779 A1
(43) Pub. Date: Jan. 29, 2009

(54) SOLAR CELL ASSEMBLY

(75) Inventor: BOR-YUAN HSIAO, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/100,266

(22) Filed: Apr. 9, 2008

(30) Foreign Application Priority Data
Jul. 26, 2007 (CN) 200710201181.4

(51) Int. Cl. H01L 31/052

(52) U.S. Cl. 136/246

(57) ABSTRACT

A solar cell assembly includes a first solar cell panel, a second solar cell panel, and at least one first light diverging lens. The first solar cell panel has at least one first through hole defined therein. The at least one first light diverging lens is embedded in the at least one first through hole of the first solar cell panel. The at least one first light diverging lens is configured for diverging sunlight incident thereupon and forming a first diverged light output. The second solar cell panel is spaced apart from the first solar cell panel and facing towards the at least one first light diverging lens. The second solar cell panel is configured for receiving and converting the first diverged light output into electric power.

### BACKGROUND

1. Technical Field

The present invention relates to solar cell assemblies, and particularly, to a solar cell assembly with a plurality of solar cell panels.

2. Description of Related Art

Currently, various solar cell assemblies have been designed to receive and convert sunlight into electrical energy. Such solar cell assemblies have been applied on roofs of buildings and cars, or applied on portable electronic devices.

Solar cell panels are key components of the solar cell assemblies. A typical solar cell panel includes a P-type semiconductor layer and an N-type semiconductor layer. When sunlight projects on surfaces of the P-type semiconductor layer or the N-type semiconductor layer, a part of the sunlight is unavoidably reflected by the surfaces, and the other is absorbed. Photons in the absorbed sunlight collide with electrons in the P-type semiconductor layer or the N-type semiconductor layer, thereby, electron-hole pairs are generated, and thus an electric field is formed between the P-type semiconductor layer and the N-type semiconductor layer. In this way, the solar cell converts solar energy into electric power.

As known, the solar energy that the solar cell panel receives is limited by the surface area exposed to the sunlight. However, due to the limited outside surface areas, buildings, cars and portable electronic devices, having a large surface area for laying out a large solar cell panel or a plurality of solar cell panels is restricted.

What is needed, therefore, is a solar cell assembly which includes a plurality of solar cell panels and each of the solar cell panels can be efficiently used.

### SUMMARY

An exemplary solar cell assembly includes a first solar cell panel, a second solar cell panel, and at least one first light diverging lens. The first solar cell panel has at least one first through hole defined therein. The at least one first light diverging lens is embedded in the at least one first through hole of the first solar cell panel. The at least one first light diverging lens is configured for diverging sunlight incident thereupon and forming a first diverged light output. The second solar cell panel is spaced apart from the first solar cell panel and facing towards the at least one first light diverging lens. The second solar cell panel is configured for receiving and converting the first diverged light output into electric power.

Other advantages and novel features of the present invention will become more apparent from the following detailed description of preferred embodiment when taken in conjunction with the accompanying drawings.

### BRIEF DESCRIPTION OF THE DRAWINGS

Many aspects of the solar cell assembly can be better understood with reference to the following drawings. The components in the drawings are not necessarily drawn to scale, the emphasis instead being placed upon clearly illustrating the principles of the present solar cell assembly. Moreover, in the drawings, like reference numerals designate corresponding parts throughout the several views.

FIG. 1 is a schematic view of a solar cell assembly in accordance with a first embodiment of the present invention.

FIG. 2 is a cut-away view of the solar cell assembly taken along II-II line shown in FIG. 1.

FIG. 3 is a cut-away view of the solar cell assembly in accordance with a second embodiment of the present invention.

FIG. 4 is a cut-away view of the solar cell assembly in accordance with a third embodiment of the present invention.

### DETAILED DESCRIPTION OF THE EMBODIMENTS

Embodiments of the present solar cell assembly will now be described in detail below and with reference to the drawings.

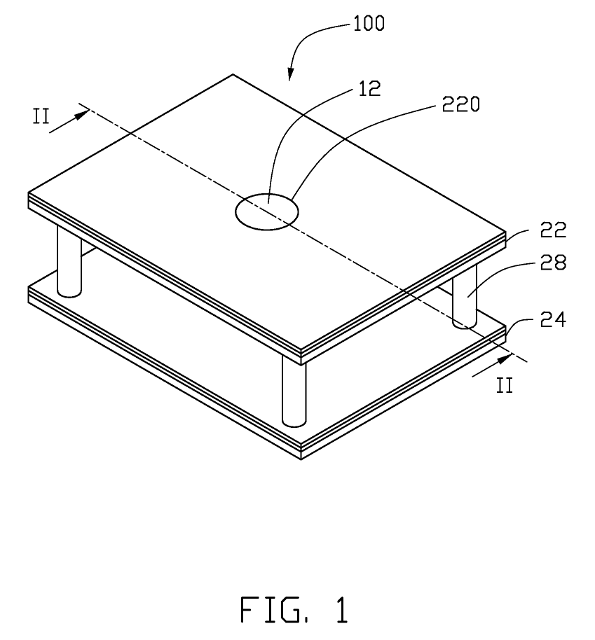

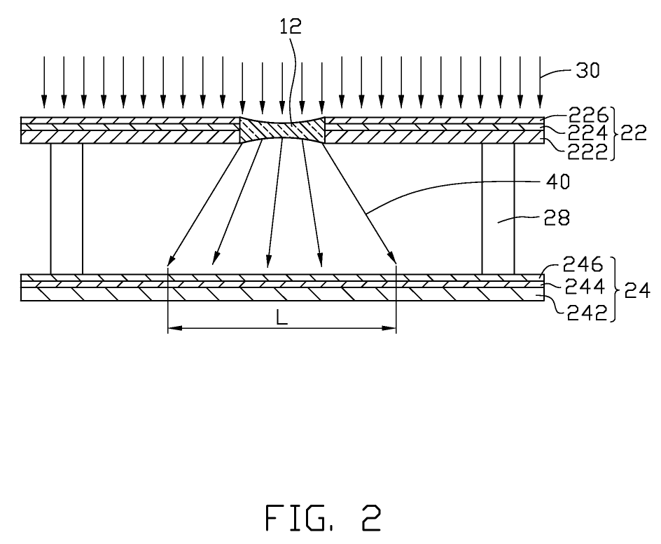

Referring to FIGS. 1 and 2, an exemplary solar cell assembly 100 in accordance with a first embodiment is shown. The solar cell assembly 100 includes a first solar cell panel 22, a second solar cell panel 24 spaced apart from the first solar cell panel 22 by four spacers 28, and a first light diverging lens 12 embedded in the first solar cell panel 22.

The first solar cell panel 22 has a first through hole 220 defined therein. The first light diverging lens 12 is embedded in the first through hole 220. The first solar cell panel 22 includes a rigid substrate 222, a P-type semiconductor layer 224 and an N-type semiconductor layer 226. The P-type semiconductor layer 224 is formed on the rigid substrate 222. The N-type semiconductor layer 226 is formed on the P-type semiconductor layer 224. The rigid substrate 222 can be made from glass. The P-type semiconductor layer 224 can be made of aluminum gallium arsenide (AlGaAs), aluminum gallium nitride doped with hydrogen (AlGaN:H), or aluminum gallium nitride doped with magnesium (AlGaN:Mg). The N-type semiconductor layer 226 can be made of gallium nitride (GaN), or gallium nitride doped with silicon (GaN:Si). A thickness of the P-type semiconductor layer 224 can be in a range from 1 to 10 microns. A thickness of the N-type semiconductor layer 226 can be in a range from 0.5 to 10 microns.

The second solar cell panel 24 is parallel with the first solar cell panel 22. The second solar cell panel 24 includes a flexible substrate 242, a P-type semiconductor layer 244 and an N-type semiconductor layer 246. The P-type semiconductor layer 244 is formed on the flexible substrate 242. The N-type semiconductor layer 246 is formed on the P-type semiconductor layer 244. The N-type semiconductor layer 246 faces toward the first solar cell panel 22. The flexible substrate 242 can be a stainless steel foil, with a thickness range from 10 to 100 microns. The P-type semiconductor layer 244 can be the same as the P-type semiconductor layer 224 of the first solar cell panel 22. The N-type semiconductor layer 246 can be the same as the N-type semiconductor layer 226 of the first solar cell panel 22.

A P-N junction layer (not shown) may be applied to each of the first and second solar cell panels 22, 24, between the respective P-type semiconductor layers 224, 244 and the N-type semiconductor layers 226, 246. The P-N junction layer may be made of copper indium gallium diselenide (CuIn₁₋ₓGaSe₂). The P-N junction layer helps to improve photon-electron conversion efficiency of each of the first and second solar cell panels 22, 24.

The first and second solar cell panels 22, 24 each are in a rectangular shape. The four spacers 28 each are in a rod shape. The four spaces 28 are positioned between the first and second solar cell panels 22, 24 and adjacent to the respective four corners of the first and second solar cell panels 22, 24. An interspace is maintained between the adjacent spacers 28. The first light diverging lens 12 can be a concave lens.

In use, the solar cell assembly 100 can be applied on, for example, a roof of a building. Due to flexibility of the flexible substrate 242, the solar cell assembly 100 can easily conform to a shape of the roof and be attached thereon. Surface area of the first solar cell panel 22 and the first light diverging lens 12 are fully and directly exposed to sunlight 30. A periphery surface area of the second solar cell panel 24 may be directly exposed to sunlight (not shown) incident from the interspace between the adjacent spacers 28 at four sides of the second solar cell panel 24, but, central surface area of the second solar cell panel 24, labeled L as shown in FIG. 2, may be not directly exposed to any sunlight. However, the first light diverging lens 12 converts the sunlight 30 incident thereupon into a first diverged light output 40, and the first diverged light output 40 casts on the central surface area of the second solar cell panel 24, thereby, compensating the light exposure of the central surface area of the second solar cell panel 24. In this way, the entire second solar cell panel 24 is able to receive sunlight or the first diverged light output 40 converted from sunlight. The second solar cell panel 24 can then convert solar energy from such light into electric power.

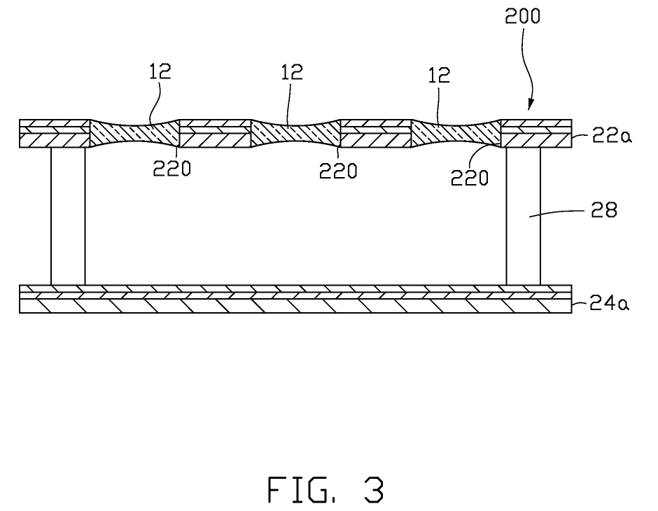

Referring to FIG. 3, an exemplary solar cell assembly 200 in accordance with a second embodiment is shown. The solar cell assembly 200 is essentially similar to the solar cell assembly 100 illustrated above, however, in the solar cell assembly 200, the first solar cell panel 22a has a number of first through holes 220 defined therein, and a number of first light diverging lenses 12 are provided and embedded in the respective first through holes 220. The first light diverging lenses 12 are able to fully compensate the light exposure of the second solar cell panel 24a. In this way, surface areas of the first and the second solar cell panels 22a, 24a in the solar cell assembly 200 can be designed more larger.

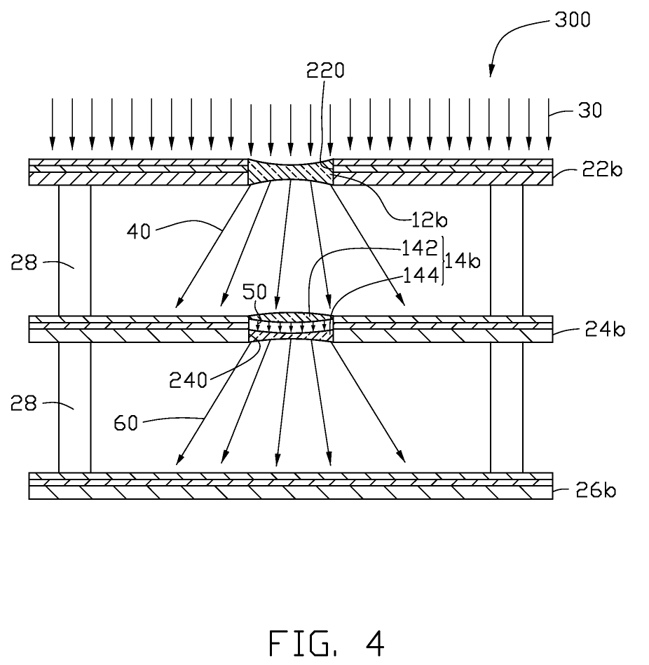

Referring to FIG. 4, an exemplary solar cell assembly 300 in accordance with a third embodiment is shown. The solar cell assembly 300 includes a first solar cell panel 22b, a second solar cell panel 24b disposed under the first solar cell panel 22b, a third solar cell panel 26b disposed under the second solar cell panel 24b, a number of spacers 28, a first light diverging lens 12b, and a second light diverging lens 14b.

The first solar cell panel 22b has a first through hole 220 defined therein. The second solar cell panel 24b has a second through hole 240 defined therein. The second through hole 240 is aligned with the first through hole 220. The spacers 28 are arranged between the first solar cell panel 22b and the second solar cell panel 24b, and between the second solar cell panel 24b and the third solar cell panel 26b. The first light diverging lens 12b is embedded in the first through hole 220 of the first solar cell panel 22b. The first light diverging lens 12b is a concave lens and configured for converting sunlight 30 into a first diverged light output 40. The second light diverging lens 14b is embedded in the second through hole 240 of the second solar cell panel 24b. The second light diverging lens 14b is composed of a convex lens portion 142 and a concave lens portion 144. The convex lens portion 142 converts the first diverged light output 40 from the first light diverging lens 12b into parallel light 50, the concave lens portion 144 then converts the parallel light 50 into a second diverged light output 60, thereby, a central surface area of the third solar cell panel 26b is exposed to the second diverged light output 60.

More solar cell panels can be employed in the solar cell assembly 300. A periphery surface area of a latter solar cell panel may be directly exposed to sunlight incident from the interspace between the adjacent spacers at four sides of the latter solar cell panel. A central surface area of a latter solar cell panel can receive diverged light output from a light diverging lens embedded in the former solar cell panel. In this way, each of the solar cell panels can be efficiently used.

It is understood that the above-described embodiments are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A solar cell assembly, comprising:
a first solar cell panel having at least one first through hole defined therein;
at least one first light diverging lens embedded in the at least one first through hole of the first solar cell panel, the at least one first light diverging lens being configured for diverging sunlight incident thereupon and forming a first diverged light output; and
a second solar cell panel spaced apart from the first solar cell panel and facing towards the at least one first light diverging lens, the second solar cell panel being configured for receiving and converting the first diverged light output into electric power.

2. The solar cell assembly as described in claim 1, further comprising a plurality of spacers spacing the first and second solar cell panels.

3. The solar cell assembly as described in claim 2, wherein an interspace is maintained between the adjacent spacers.

4. The solar cell assembly as described in claim 1, wherein the first solar cell panel comprises a rigid substrate.

5. The solar cell assembly as described in claim 1, wherein the second solar cell panel comprises a flexible substrate.

6. The solar cell assembly as described in claim 5, wherein the flexible substrate is a stainless steel foil.

7. The solar cell assembly as described in claim 1, wherein the at least one first light diverging lens is a concave lens.

8. The solar cell assembly as described in claim 1, further comprising a third solar cell panel and a second light diverging lens, the second solar cell panel having a second through hole defined therein, the second light diverging lens being embedded in the second through hole, the third solar cell panel spaced apart from the second solar cell panel and facing towards the second light diverging lens, the second diverging lens being configured for receiving and converting the first diverged light output into a second diverged light output, the third solar cell panel being configured for receiving and converting the second diverged light output into electric power.

9. The solar cell assembly as described in claim 8, wherein the first and second solar cell panels each comprise a rigid substrate.

10. The solar cell assembly as described in claim 8, wherein the third solar cell panel comprises a flexible substrate.

11. The solar cell assembly as described in claim 8, wherein the second light diverge lens comprises a convex lens portion and a concave lens portion, the convex lens portion being configured for converting the first diverged light output into parallel light, the concave lens portion being configured for converting the parallel light into the second diverged light output.
